(19) United States
(12) Patent Application Publication
(10) Pub. No.: US 2007/0096086 A1
(43) Pub. Date: May 3, 2007

(54) Hole injection electrode

(76) Inventors: Ying Wang, Wilmington, DE (US); William Raymond Salaneck, Linkoping (SE); Slawomir Braun, San Luis Obispoon, CA (US)

Correspondence Address: E I DU PONT DE NEMOURS AND COMPANY;LEGAL PATENT RECORDS CENTER, BARLEY MILL PLAZA 25/1128, 4417 LANCASTER PIKE, WILMINGTON, DE, 19805, US

(21) Appl. No.: 11/475,407

(22) Filed: Jun. 27, 2006

Related U.S. Application Data
(60) Provisional application No. 60/694,272, filed on Jun. 27, 2005.

(51) Int. Cl. H01L 29/08; H01L 35/24; H01L 51/00

(52) U.S. Cl. 257/40

(57) ABSTRACT

There is provided an electrode having a first layer of a metallic material having a work function greater than 4.0 eV and a second layer of an organic material having an electron affinity greater than 4.0 eV. The second layer has a thickness in the range of 0.5 to 5 nm.

### RELATED U.S. APPLICATIONS

This application claims priority to U.S. provisional application, Ser. No. 60/694272, dated Jun. 27, 2005.

### BACKGROUND INFORMATION

1. Field of the Disclosure

This disclosure relates in general to hole injection electrodes, and, in particular, to hole injection electrodes useful in organic electronic devices.

2. Description of the Related Art

Increasingly, active organic molecules are used in electronic devices. Electronic devices that incorporate organic active materials may be used to convert electrical energy into radiation and may include a light-emitting diode, light-emitting diode display, or diode laser.

In the devices, the organic active layer is sandwiched between two electrical contact layers. In general, one contact layer is a hole-injecting electrode and the other is an electron-injecting electrode. In, for example, a light-emitting diode (“OLED”) display, the organic active layer emits light through the light-transmitting electrical contact layer upon application of a voltage across the electrical contact layers. OLEDs also frequently have a buffer layer and/or hole-transporting layer adjacent to the hole-injecting electrode, and can have an electron-injecting layer adjacent to the electron-injecting electrode.

Indium tin oxide (“ITO”) is commonly used as the electrode for injecting holes into an OLED device. To have efficient hole injection, the barrier for injection from the ITO to the adjacent layer, typically the buffer layer, has to be low. The barrier is defined as the difference between the work function of the ITO and the ionization potential of the buffer layer. The work function of ITO is typically between 4.5 to 4.8 eV, depending on the processing conditions, while most of the buffer materials have ionization potentials larger than 5 eV.

Therefore, a need exists for hole-injecting electrodes having a work function higher than that of ITO.

### SUMMARY

There is provided an electrode comprising a first layer of a metallic material having a work function greater than 4.0 eV and a second layer of an organic material having an electron affinity greater than 4.0 eV, wherein the second layer has a thickness in the range of 0.5 to 5 nm.

In another embodiment, there is provided an organic electronic device comprising the new electrode.

The foregoing general description and the following detailed description are exemplary and explanatory and are not restrictive of the invention, as defined in the appended claims.

### BRIEF DESCRIPTION OF THE DRAWINGS

The invention is illustrated by way of example and not limitation in the accompanying figures.

FIG. 1 is a schematic diagram of an organic electronic device.

FIG. 2 is plot of the X-ray photoelectron spectroscopy signal and work function vs. layer thickness of an F₄-TCNQ film.

FIG. 3 is a plot of ultraviolet photoelectron spectroscopy spectra of F₄-TCNQ films having different thicknesses.

FIG. 4 is a theoretical ultraviolet photoelectron spectroscopy spectrum.

FIG. 5 gives atomic force microscopy results.

FIG. 6 is a plot of current-voltage curves for devices with the new electrode.

Skilled artisans appreciate that objects in the figures are illustrated for simplicity and clarity and have not necessarily been drawn to scale. For example, the dimensions of some of the objects in the figures may be magnified relative to other objects to help to improve understanding of embodiments.

### DETAILED DESCRIPTION

There is provided a new electrode comprising a first layer of a metallic material having a work function greater than 4.0 eV and a second layer of an organic material having an electron affinity greater than 4.0 eV, wherein the second layer has a thickness in the range of 0.5 to 5 nm.

Many aspects and embodiments are described herein and are exemplary and not limiting. After reading this specification, skilled artisans appreciate that other aspects and embodiments are possible without departing from the scope of the invention.

As used herein, the term “metallic” is intended to mean containing one or more metals. For example, a metallic coating can include an elemental metal by itself, a clad, an alloy, an oxide, a plurality of layers of any combination of elemental metal(s), clad(s), alloy(s), oxide(s), or any combination thereof. The term “work function” is intended to mean the minimum energy needed to remove an electron from a material to a point at infinite distance away from the surface. The term “organic” is intended to mean the class of chemical compounds having a carbon basis. The term “electron affinity” is intended to mean the change in potential involved in vacuum in the reduction of (i) a positive ion to an ion of less positive charge or a neutral molecule, (ii) a. neutral molecule to a negative ion, or (iii) a negative ion to a more negative ion. The term “active” when referring to a layer or material is intended to mean a layer or material that exhibits electronic or electro-radiative properties. An active layer material electronically facilitates the operation of the device comprising such layer or material.

In one embodiment, the metallic material of the first layer is selected from a metal, mixed metals, alloy, metal oxide or mixed oxide. Suitable materials include, but are not limited to, the mixed oxides of the Group 2 elements (i.e., Be, Mg, Ca, Sr, Ba, Ra), the Group 11 elements, the elements in Groups 4, 5, and 6, and the Group 8-10 transition elements. In one embodiment, the electrode is intended to be light-transmitting. The metallic material is selected from mixed oxides of Groups 12, 13 and 14 elements, such as indium-tin-oxide. As used herein, the phrase “mixed oxide” refers to oxides having two or more different cations selected from the Group 2 elements or the Groups 12, 13, or 14 elements. Some non-limiting, specific examples of materials for the metallic material include, but are not limited to, indium-tin-oxide (“ITO”), indium-zinc-oxide (“IZO”), aluminum-tin-oxide, gold, silver, copper, and nickel. In one embodiment, the metallic material is selected from ITO and IZO. As used herein, group numbers corresponding to columns within the periodic table of the elements use the “New Notation” convention as seen in the CRC Handbook of Chemistry and Physics, 81^{st} Edition (2000), where the groups are numbered from left to right as 1-18.

In one embodiment, the metallic materials are selected from indium tin oxide, gold, silver, and alloys and mixtures thereof.

In one embodiment, the first metallic layer has a thickness in the range of 500 to 5000 Å. In one embodiment, the first metallic layer has a thickness in the range of 1000 to 3000 Å.

In one embodiment, the organic material of the second layer is a hole injection material. As used herein, the term “hole injection” when referring to a layer, material, member, or structure, is intended to mean that such layer, material, member, or structure facilitates injection and migration of positive charges through the thickness of such layer, material, member, or structure with relative efficiency and small loss of charge. In one embodiment, the hole injection material has at least one substituent selected from F and CF₃. In one embodiment, the organic material is tetrafluorotetracyanoquinodimethane (“F4-TCNQ”).

The second layer of organic material has a thickness in the range of about 0.5 to 5 nm. In one embodiment, the thickness is in the range of about 1 to 3 nm. In one embodiment, the thickness is about 1 nm.

As used herein, the term “layer” is used interchangeably with the term “film” and refers to a coating covering a desired area. The term is not limited by size. The area can be as large as an entire device or as small as a specific functional area such as the actual visual display, or as small as a single sub-pixel. A “material” can also be a “layer” or a “film”.

The layers of the new electrode can be formed by any conventional deposition technique, including vapor deposition, liquid deposition (continuous and discontinuous techniques), and thermal transfer. Continuous deposition techniques, include but are not limited to, spin coating, gravure coating, curtain coating, dip coating, slot-die coating, spray coating, and continuous nozzle coating. Discontinuous deposition techniques include, but are not limited to, ink jet printing, gravure printing, and screen printing.

In one embodiment, the layers of the new electrode are formed by a chemical or physical vapor deposition process or spin-coating process. Chemical vapor deposition may be performed as a plasma-enhanced chemical vapor deposition (“PECVD”) or metal organic chemical vapor deposition (“MOCVD”). Physical vapor deposition can include all forms of sputtering, including ion beam sputtering, as well as e-beam evaporation and resistance evaporation. Specific forms of physical vapor deposition include rf magnetron sputtering and inductively-coupled plasma physical vapor deposition (“IMP-PVD”). These deposition techniques are well known within the semiconductor fabrication arts.

In one embodiment the electron device is any device requiring an electrode.

In one embodiment, there is provided an organic electronic device comprising the new electrode. The term “organic electronic device” or sometimes just “electronic device” is intended to mean a device including one or more organic semiconductor layers or materials. An organic electronic device includes, but is not limited to: (1) a device that converts electrical energy into radiation (e.g., a light-emitting diode, light emitting diode display, diode laser, or lighting panel), (2) a device that detects a signal using an electronic process (e.g., a photodetector, a photoconductive cell, a photoresistor, a photoswitch, a phototransistor, a phototube, an infrared (“IR”) detector, or a biosensors), (3) a device that converts radiation into electrical energy (e.g., a photovoltaic device or solar cell), (4) a device that includes one or more electronic components that include one or more organic semiconductor layers (e.g., a transistor or diode), or any combination of devices in items (1) through (4).

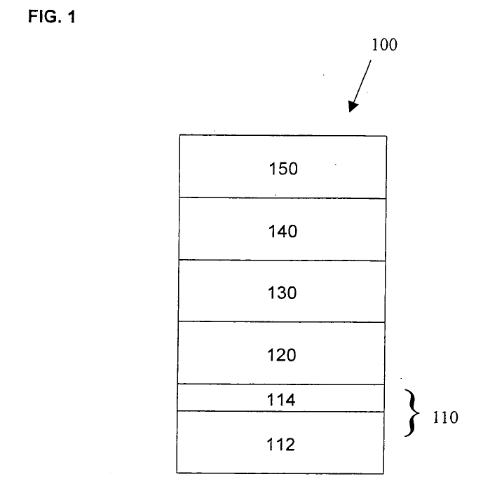

As shown in FIG. 1, one type of an electronic device, 100, has an anode layer 110, a buffer layer 120, an electroactive layer 130, and a cathode layer 150. Adjacent to the cathode layer 150 is an optional electron-injection/transport layer 140. The anode comprises a first metallic layer 112 and a second organic layer 114.

The device may include a support or substrate (not shown) that can be adjacent to the anode layer 110 or the cathode layer 150. Most frequently, the support is adjacent the anode layer 110. The support can be flexible or rigid, organic or inorganic. Examples of support materials include, but are not limited to, glass, ceramic, metal, and plastic films.

The buffer layer 120 comprises electrically conductive or semiconductive materials and may have one or more functions in an organic electronic device, including but not limited to, planarization of the underlying layer, charge transport and/or charge injection properties, scavenging of impurities such as oxygen or metal ions, and other aspects to facilitate or to improve the performance of the organic electronic device. Buffer materials may be polymers, solutions, dispersions, suspensions, emulsions, colloidal mixtures, or other compositions.

In one embodiment, the buffer layer 120 comprises hole transport material(s). Examples of hole transport materials for layer 120 have been summarized for example, in Kirk-Othmer Encyclopedia of Chemical Technology, Fourth Edition, Vol. 18, p. 837-860,1996, by Y. Wang. Both hole transporting molecules and polymers can be used. Commonly used hole transporting molecules include, but are not limited to: 4,4′,4“-tris(N,N-diphenyl-amino)-triphenylamine (TDATA); 4,4′,4“-tris(N-3-methylphenyl-N-phenyl-amino)-triphenylamine (MTDATA); N,N′-diphenyl-N,N′-bis(3-methylphenyl)-[1,1′-biphenyl]-4,4′-diamine (TPD); 1,1-bis[(di-4-tolylamino)phenyl]cyclohexane (TAPC); N,N′-bis(4-methylphenyl)-N,N′-bis(4-ethylphenyl)-[1,1′-(3,3′-dimethyl)biphenyl]4,4′-diamine (ETPD); tetrakis-(3-methylphenyl)-N,N,N′,N′-2,5-phenylenediamine (PDA); α-phenyl4-N,N-diphenylaminostyrene (TPS); p-(diethylamino)benzaldehyde diphenylhydrazone (DEH); triphenylamine (TPA); bis[4-(N,N-diethylamino)-2-methylphenyl](4-methylphenyl)methane (MPMP); 1-phenyl-3-[p-(diethylamino)styryl]-5-[p-(diethylamino)phenyl]pyrazoline (PPR or DEASP); 1,2-trans-bis(9H-carbazol-9-yl)cyclobutane (DCZB); N,N,N′,N′-tetrakis(4-methylphenyl)-(1,1′-biphenyl)4,4′-diamine (TTB); N,N′-bis(naphthalen-1-yl)-N,N′-bis-(phenyl)benzidine (α-NPB); and porphyrinic compounds, such as copper phthalocyanine. Commonly used hole transporting polymers include, but are not limited to, polyvinylcarbazole, (phenylmethyl)polysilane, poly(dioxythiophenes), polyanilines, and polypyrroles. It is also possible to obtain hole transporting polymers by doping hole transporting molecules such as those mentioned above into polymers such as polystyrene and polycarbonate.

In one embodiment, the buffer material comprises a layer made from an aqueous dispersion of a conductive polymer and polymeric acid colloids. In one embodiment, the polymeric acid colloids comprise a polymeric fluorinated sulfonic acid. In one embodiment, the conductive polymer is selected from poythiophenes, polyanilines, and polypyrroles. Such materials have been disclosed in published PCT applications WO 2004/029128, WO 2004/029133, and WO 2004/029176.

The electroluminescent (EL) layer 130 may typically be any organic EL material, including, but not limited to, small molecule organic fluorescent compounds, fluorescent and phosphorescent metal complexes, conjugated polymers, and mixtures thereof. Examples of fluorescent compounds include, but are not limited to, pyrene, perylene, rubrene, coumarin, derivatives thereof, and mixtures thereof. Examples of metal complexes include, but are not limited to, metal chelated oxinoid compounds, such as tris(8-hydroxyquinolato)aluminum (Alq3); cyclometalated iridium and platinum electroluminescent compounds, such as complexes of iridium with phenylpyridine, phenylquinoline, or phenylpyrimidine ligands as disclosed in Petrov et al., U.S. Pat. No. 6,670,645 and Published PCT Applications WO 03/063555 and WO 2004/016710, and organometallic complexes described in, for example, Published PCT Applications WO 03/008424, WO 03/091688, and WO 03/040257, and mixtures thereof. Electroluminescent emissive layers comprising a charge carrying host material and a metal complex have been described by Thompson et al., in U.S. Pat. No. 6,303,238, and by Burrows and Thompson in published PCT applications WO 00/70655 and WO 01/41512. Examples of conjugated polymers include, but are not limited to poly(phenylenevinylenes), polyfluorenes, poly(spirobifluorenes), polythiophenes, poly(p-phenylenes), copolymers thereof, and mixtures thereof.

The particular material chosen may depend on the specific application, potentials used during operation, or other factors. The EL layer 130 containing the electroluminescent organic material can be applied using any number of techniques including vapor deposition, solution processing techniques or thermal transfer. In another embodiment, an EL polymer precursor can be applied and then converted to the polymer, typically by heat or other source of external energy (e.g., visible light or UV radiation).

Optional layer 140 can function both to facilitate electron injection/transport, and can also serve as a confinement layer to prevent quenching reactions at layer interfaces. More specifically, layer 140 may promote electron mobility and reduce the likelihood of a quenching reaction if layers 130 and 150 would otherwise be in direct contact. Examples of materials for optional layer 140 include, but are not limited to, metal chelated oxinoid compounds, such as tris(8-hydroxyquinolato)aluminum (Alq3), bis(2-methyl-8-quinolinolato)(para-phenyl-phenolato)aluminum(III) (BAIQ), and tetrakis-(8-hydroxyquinolinato)zirconium (IV) (ZrQ); and azole compounds such as 2-(4-biphenylyl)-5-(4-t-butylphenyl)-1,3,4-oxadiazole (PBD), 3-(4-biphenylyl)-4-phenyl-5-(4-t-butylphenyl)-1,2,4-triazole (TAZ), and 1,3,5-tri(phenyl-2-benzimidazole)benzene (TPBI); quinoxaline derivatives such as 2,3-bis(4-fluorophenyl)quinoxaline; phenanthrolines such as 4,7-diphenyl-1,10-phenanthroline (DPA) and 2,9-dimethyl-4,7-diphenyl-1,10-phenanthroline (DDPA); and mixtures thereof. Alternatively, optional layer 140 may be inorganic and comprise BaO, LiF, Li₂O, or the like.

The cathode layer 150 is an electrode that is particularly efficient for injecting electrons or negative charge carriers. The cathode layer 150 can be any metal or nonmetal having a lower work function than the first electrical contact layer (in this case, the anode layer 110).

Materials for the cathode layer can be selected from alkali metals of Group 1 (e.g., Li, Na, K, Rb, Cs,), the Group 2 metals (e.g., Mg, Ca, Ba, or the like), the Group 12 metals, the lanthanides (e.g., Ce, Sm, Eu, or the like), and the actinides (e.g., Th, U, or the like). Materials such as aluminum, indium, yttrium, and combinations thereof, may also be used. Specific non-limiting examples of materials for the cathode layer 150 include, but are not limited to, barium, lithium, cerium, cesium, europium, rubidium, yttrium, magnesium, samarium, and alloys and combinations thereof.

The cathode layer 150 is usually formed by a chemical or physical vapor deposition process. In general, the cathode layer will be patterned, as discussed above in reference to the anode layer 110. If the device lies within an array, the cathode layer 150 may be patterned into substantially parallel strips, where the lengths of the cathode layer strips extend in substantially the same direction and substantially perpendicular to the lengths of the anode layer strips. Electronic elements called pixels are formed at the cross points (where an anode layer strip intersects a cathode layer strip when the array is seen from a plan or top view).

In other embodiments, additional layer(s) may be present within organic electronic devices. For example, a layer (not shown) between the buffer layer 120 and the EL layer 130 may facilitate positive charge transport, band-gap matching of the layers, function as a protective layer, or the like. Similarly, additional layers (not shown) between the EL layer 130 and the cathode layer 150 may facilitate negative charge transport, band-gap matching between the layers, function as a protective layer, or the like. Layers that are known in the art can be used. In addition, any of the above-described layers can be made of two or more layers. Alternatively, some or all of inorganic anode layer 110, the buffer layer 120, the EL layer 130, and cathode layer 150, may be surface treated to increase charge carrier transport efficiency. The choice of materials for each of the component layers may be determined by balancing the goals of providing a device with high device efficiency with the cost of manufacturing, manufacturing complexities, or potentially other factors. The different layers may have any suitable thickness. In one embodiment, buffer layer 120, is usually no greater than approximately 250 nm, for example, approximately 50-200 nm; EL layer 130, is usually no greater than approximately 100 nm, for example, approximately 50-80 nm; optional layer 140 is usually no greater than approximately 100 nm, for example, approximately 20-80 nm; and cathode layer 150 is usually no greater than approximately 100 nm, for example, approximately 1-50 nm.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

Also, use of the “a” or “an” are employed to describe elements and components of the invention. This is done merely for convenience and to give a general sense of the invention. This description should be read to include one or at least one and the singular also includes the plural unless it is obvious that it is meant otherwise.

Unless otherwise defined, all technical and scientific terms used herein have the same meaning as commonly understood by one of ordinary skill in the art to which this invention belongs. Although methods and materials similar or equivalent to those described herein can be used in the practice or testing of the present invention, suitable methods and materials are described below. All publications, patent applications, patents, and other references mentioned herein are incorporated by reference in their entirety. In case of conflict, the present specification, including definitions, will control. In addition, the materials, methods, and examples are illustrative only and not intended to be limiting.

It is to be appreciated that certain features of the invention which are, for clarity, described above and below in the context of separate embodiments, may also be provided in combination in a single embodiment. Conversely, various features of the invention that are, for brevity, described in the context of a single embodiment, may also be provided separately or in any subcombination.

### EXAMPLES

### Example 1

ITO substrates were cleaned by different procedures as follows: (a) ultra-sonification in detergent, then acetone, and then isopropanol, followed by rinsing with deionized water, then drying in a stream of dry nitrogen; (b) as previously, but in addition, annealing in vacuum at 200° C.; and (c) as in (a) but followed by UV-ozone cleaning for 10 min. The sample was then immediately inserted into the vacuum chamber of the spectrometer. Spectra were recorded by ultraviolet photoelectron spectroscopy (“UPS”), using monochromatized He I (21.2 eV) radiation. X-ray photoelectron spectroscopy (“XPS”) measurements were performed using non-monochromatized Al K_{α} x-rays (1486.6 eV).

F4-TCNQ was deposited by thermal evaporation from a resistively-heated crucible. Before deposition, the molecules were heated to the sublimation temperature and thoroughly out-gassed. The substrate was cooled to −100° C. to enhance condensation of the molecules on the surface. A monolayer of F4-TCNQ was achieved by desorption of the multilayer. Desorption of the multilayer film was accomplished in situ by heating the substrate to 200° C. The process was monitored by UPS, and the procedure was continued until no changes to the spectra were observed. XPS measurements were done to confirm monolayer formation. At monolayer coverage, the F/In ratio was 0.15 as measured by XPS.

The work function of F4-TCNQ modified ITO is listed in Table 1 with different ITO cleaning conditions.

TABLE 1
Work function of bare ITO and F4-TCNQ modified
ITO with different ITO cleaning procedures.

| | Cleaning procedure | | |
|---|---|---|---|
| | Detergent (a) | Annealing (b) | UV-ozone |
| surface | Work function (eV) | | |
| Bare ITO | 4.5-4.6 | 4.7 | 4.8 |
| F4-TCNQ monolayer | 5.2 | 5.2 | 5.2 |

### Example 2

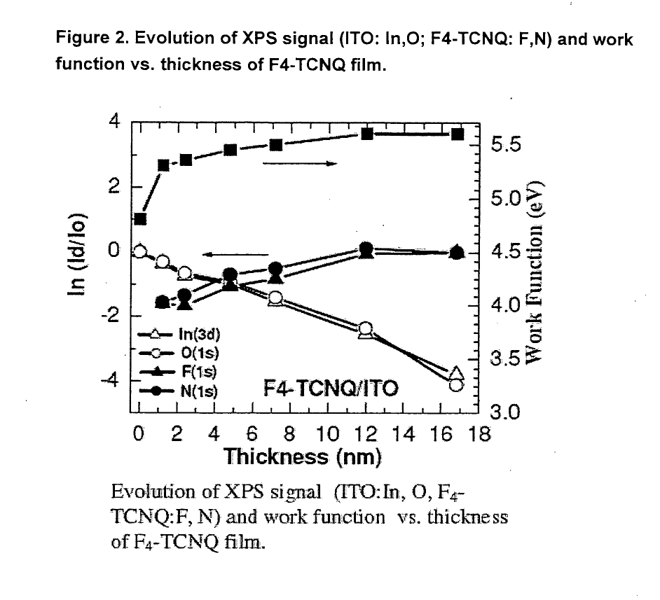

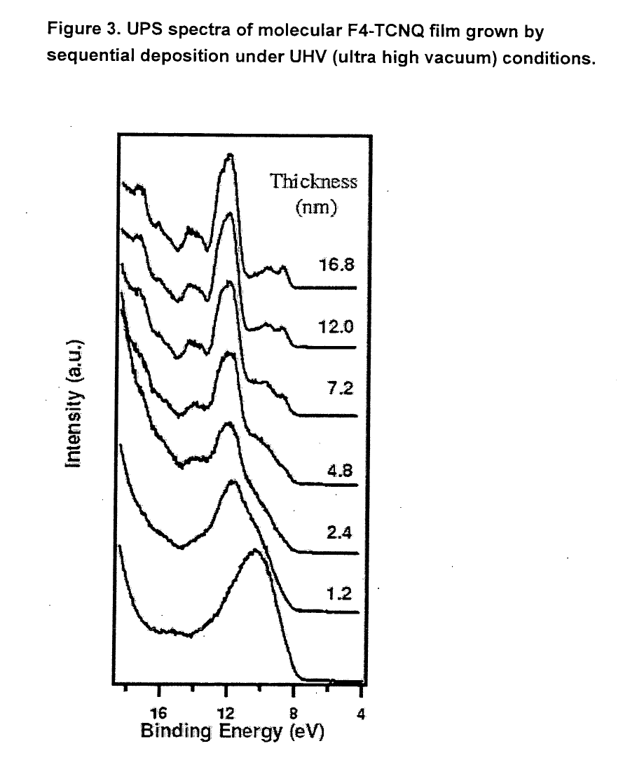

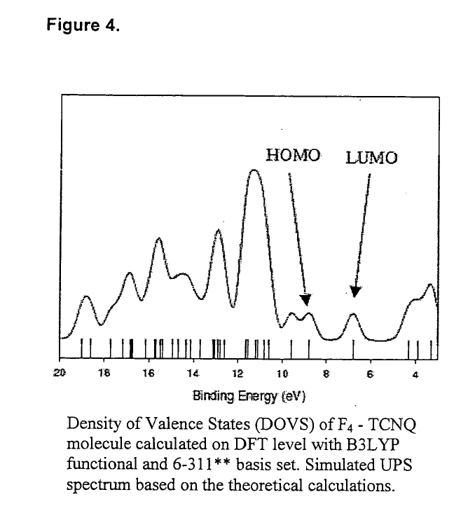

F4-TCNQ films were grown by sequential thermal deposition onto ITO substrates. XPS and UPS measurements were made after each deposition. The coverage on the ITO, after each deposition step, was given by the ratio between concentration of F and In atoms. In is the characteristic element of ITO and F is a fingerprint signal for obtaining the coverage of the F4-TCNQ. As can be seen in FIG. 2 the deposition of 1.2 nm thick molecular film of F₄-TCNQ onto ITO substrate resulted in the work function increase of 0.5 eV (from 4.8 eV for bare ITO to 5.3 eV for F₄-TCNQ/ITO). Further deposition of the molecules resulted in an increase of the work function to 5.6 eV. The value of work function remained constant as soon as 12 nm of the molecular material was deposited. UPS spectra taken after each deposition step of F₄-TCNQ molecular layer showed that the signal characteristic of ITO changed slowly towards that characteristic od F₄-TCNQ (see FIG. 3). After 12 nm of the molecular layer was deposited, the UPS spectra finally resembled that characteristic of F₄-TCNQ molecules. Quantum chemical calculations were performed in order to obtain the Density of Valence States (DOVS), which then were used to plot theoretical UPS spectrum, shown in FIG. 4. The spectrum matches closely to the experimental results.

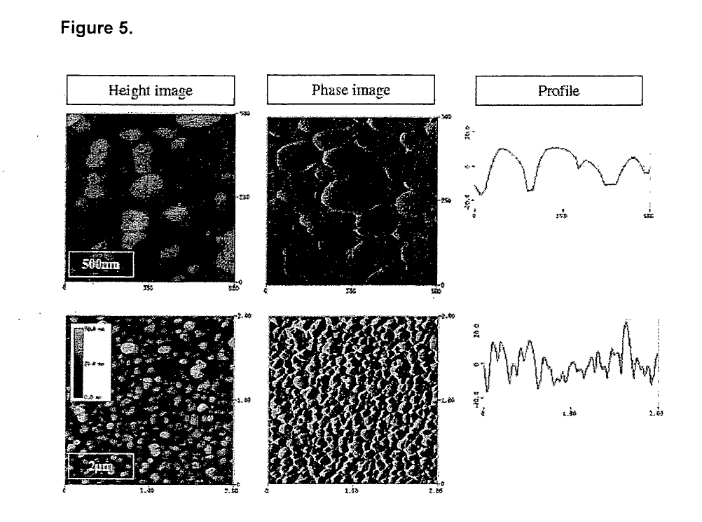

The XPS spectra taken after each deposition step revealed that the intensity of In(indium) and O (oxygen) photoelectron signals, which are characteristic of the ITO substrate, decreased slowly with the increasing coverage of F₄-TCNQ. The F (fluorine) and N(nitrogen) signals increased gradually with the thickness of the F₄-TCNQ film to finally achieve their saturation intensity for the 12 nm thick F₄-TCNQ growth. Further confirmation of island growth were given by the AFM (Atomic Force Microscopy) results, shown on FIG. 5. This indicated that a continuous monolayer cannot be obtained by sequential growth because of the tendency for island growth. Hence the procedures used in Example 1 need to be used to get continuous monolayer coverage of F₄-TCNQ on ITO. XPS data, together with UPS data, indicated island type.

### Example 3

F4-TCNQ was deposited onto a polycrystalline gold electrode. Before deposition, the gold electrode had a work function of 5.0 eV. After depositing a multilayer F4-TCNQ, the work function increased to 5.4 eV. After annealing at 100° C., the work function further increased to 5.5 eV. This example demonstrates that a F4-TCNQ modified gold electrode has a higher work function.

### Example 4

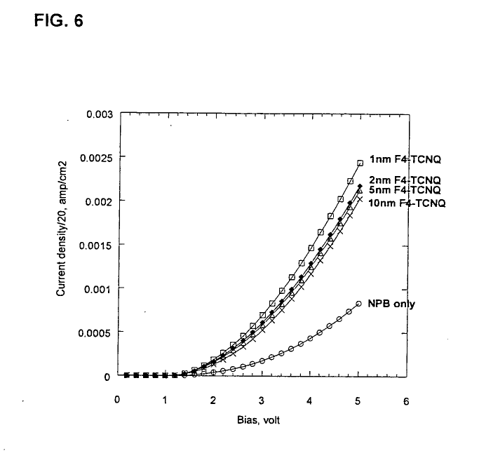

Hole only devices were fabricated to study hole injection from F4-TCNQ modified ITO electrode to a commonly used hole transport material, α-NPB, with the following molecular structure: 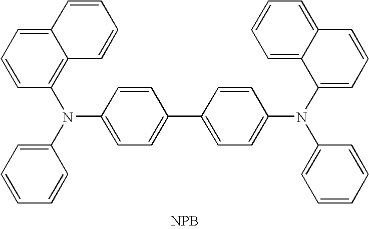
A control device was made of ITO/NPB(200 nm)/AI(100 nm) which was compared to the test devices of ITO/F4-TCNQ(various thickness)/NPB(200 nm)/Al(100 nm). FIG. 6 shows the current-voltage curves for these devices. As can be seen, with ITO electrode modified by 1 nm of F4-TCNQ, the injected hole current was enhanced by about a factor of 3 at 5V compared to NPB-only device. With thicker F4-TCNQ, there was a slight reduction of injected current but still much higher than NPB-only device. This example demonstrated enhanced hole injection of F4-TCNQ modified ITO into hole transport material.

Note that not all of the activities described above in the general description or the examples are required, that a portion of a specific activity may not be required, and that one or more further activities may be performed in addition to those described. Still further, the order in which activities are listed are not necessarily the order in which they are performed.

In the foregoing specification, the concepts have been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

It is to be appreciated that certain features of the invention which are, for clarity, described above and below in the context of separate embodiments, may also be provided in combination in a single embodiment. Conversely, various features of the invention that are, for brevity, described in the context of a single embodiment, may also be provided separately or in any subcombination. Further reference to values stated in ranges includes each and every value with that range.

What is claimed is:

1. An electrode comprising a first layer of a metallic material having a work function greater than 4.0 eV and a second layer of an organic material having an electron affinity greater than 4.0 eV, wherein the second layer has a thickness in the range of 0.5 to 5 nm.

2. The electrode of claim 1, wherein the metallic material comprises metals, mixed metals, alloys, metal oxides, or mixed metal oxides of Groups 3, 4, 5, 6, and 8-14 elements.

3. The electrode of claim 1, wherein the metallic material is selected from indium tin oxide, gold, silver, and alloys and mixtures thereof.

4. The electrode of claim 1, wherein the organic material has at least one substituent selected from F and CF₃.

5. The electrode of claim 1, wherein the organic material is tetrafluorotetracyanoquinodimethane.

6. The electrode of claim 1, wherein the second layer has a thickness in the range of 1 to 3 nm.

7. An organic electronic device comprising an electrode comprising a first layer of a metallic material having a work function greater than 4.0 eV and a second layer of an organic material having an electron affinity greater than 4.0 eV, wherein the second layer has a thickness in the range of 0.5 to 5 nm.
